(19) United States
(12) Patent Application Publication
(10) Pub. No.: US 2012/0174971 A1
(43) Pub. Date: Jul. 12, 2012

(54) Design and Fabrication of Dilute Nitride Material and Multi-Quantum Well Solar Cells

(75) Inventors: Alexandre Freundlich, Houston, TX (US); Andenet Alemu, Houston, TX (US)

(73) Assignee: UNIVERSITY OF HOUSTON, Houston, TX (US)

(21) Appl. No.: 13/194,012

(22) Filed: Jul. 29, 2011

Related U.S. Application Data
(60) Provisional application No. 61/368,673, filed on Jul. 29, 2010.

(51) Int. Cl. H01L 31/0304; B82Y 99/00

(52) U.S. Cl. 136/255; 977/755; 977/819

(57) ABSTRACT

Multi-junction solar cell devices which incorporate dilute nitrides to include a sub-cell in the 1 eV range in a conventional design for a solar cell. Sub-cells may be inserted within the intrinsic region of a conventional GaAs p-i-n solar cell either as a 3rd junction (1 eV) in a (Al)InGaP (1.9 eV)/GaAs(1.42 eV)/MQW(1 eV)/Ge(0.66 eV) quadruple junction device or as a triple junction configuration with a 1.1 eV MQW between GaInP (1.8 eV) and Ge(0.66 eV).

### CROSS-REFERENCES TO RELATED APPLICATIONS

This patent application claims priority to and the benefit of Provisional Patent Application Ser. No. 61/368,673 filed Jul. 29, 2010.

### FEDERALLY SPONSORED RESEARCH OR DEVELOPMENT

Not Applicable.

### REFERENCE TO A “SEQUENTIAL LISTING”

Not Applicable.

### FIELD

The present disclosure relates to the design and fabrication of solar cells. Specifically, the present disclosure relates to the use of GaAsN epilayers in multi-junction solar cells.

### BACKGROUND

Solar cells convert solar radiation and other light into usable electrical energy. In a typical solar cell, solar radiation such as sunlight impinges on the solar cell and is absorbed by an active region of semiconductor material such as a film of silicon (Si) and/or gallium arsenide (GaAs), which generates electron-hole pairs in the active region. The electrons and holes may be separated by an electric field of a junction in the solar cell. It is this separation of the electrons and holes by the junction that results in the generation of a photocurrent.

Doping may create these electrons and holes. For instance, n-doping, i.e., doping a Group IV substrate with a Group V element, creates the extra electron in the conduction band. In contrast, p-doping, i.e., doping a Group IV substrate with a Group III element, creates a “hole” where an electron is missing to fill the valence band. It is the pairing of Group III and Group V elements that leads to the III-V semiconductors. One such solar cell is the conventional Gallium/Arsenic (Ga/As) p-i-n solar cell. Free holes and electrons are termed “mobile charge carriers.” “Majority carriers” are conduction-band electrons in an n-type semi-conductor or the number of holes in a p-type semi-conductor. “Minority carriers” are the conduction band electrons in a p-type semiconductor or the holes in the n-type semiconductor.

Efficiency of solar cells has long been a problem for solar cells, including thin film solar cells. Single junction solar cell designers attempt to maximize efficiency by optimizing the tradeoff between current and voltage by choosing optimal bandgaps near the middle of the energy spectrum of the solar spectrum. The development of multi-junction solar cells allows a solar cell designer much more flexibility. Multi-junction solar cells use a combination of different semiconductor materials to capture a larger range of photon energies. Theoretically, the more junctions, the more photon energy can be captured without wasting energy as heat or losing energy from low energy photons.

As discussed in “Basic Physics and Design of III-V Solar Cells, Brenton Burnett, http://photochemistry.epfl.ch/EDEWNREL.pdf, “The next generation of multi junction solar cells may have four layers. The most direct path to such an achievement is to develop a 1.0-eV bandgap material that is lattice matched with the GaInP, GaAs, and Ge of the present triple junction solar cell.” However, the severe degradation of minority carrier properties associated with the introduction of dilute amounts of nitrogen in III-V semiconductors has been a serious hindrance toward the development of efficient 1 eV InGaAsN subcells for GaAs-based ultra-efficient quadruple junction solar cells. What is needed is a method for overcoming the deficiencies to increase the efficiency of the quadruple junction solar cell.

### SUMMARY

Multi-junction solar cells with sub-cells having similar lattice parameters but different bandgaps such as InGaP (1.9 eV), GaAs (1.42 eV) and Ge (0.66 eV) demonstrate high photo-conversion efficiencies (M. A. Green, 2009). However, the large energy difference between GaAs and Ge results in an energy loss above the bandgap of Ge.

The present application discloses solar cell devices which incorporate dilute nitrides inserted in a conventional sub-cell to form a 1 eV bandgap range device as part of multi-junction solar cell design. Such sub-cells may be formed by inserting dilute nitrides within the intrinsic region of a conventional GaAs p-i-n solar cell either as a 3rd junction (1 eV) in a (Al)InGaP (1.9 eV)/GaAs(1.42 eV)/MQW(1 eV)/Ge(0.66 eV) quadruple junction device or as a triple junction configuration with a 1.1 eV MQW between GaInP (1.8 eV) and Ge(0.66 eV).

The features and advantages of the present invention will be apparent to those skilled in the art. While numerous changes may be made by those skilled in the art, such changes are within the spirit of the invention.

### BRIEF DESCRIPTION OF THE DRAWINGS

A more complete understanding of the present disclosure and advantages thereof may be acquired by referring to the following description taken in conjunction with the accompanying figures, wherein:

FIG. 1 shows a schematic representation of a 4 junction tandem design where the 3^{rd} subcell, operating behind GaAs 2^{nd} subcell, contains dilute nitride quantum wells with an effective MQW bandgap of ˜1 eV.

FIG. 2. Schematic representation of a 3 junction tandem design where the middle (2^{nd} subcell) contains dilute nitride quantum wells with an effective MQW bandgap of ˜1.1 eV.

FIG. 3 is a schematic representation of fabricated bulk like GaAsN samples consistent with the present disclosure.

FIG. 4 is a graph comparing the intensity versus the Bragg angle for GaAsN for two different nitrogen concentrations of fabricated samples consistent with the present disclosure.

FIG. 5 is a graph comparing the photoluminescence (PL) signal Intensity (log scale) versus band gap energy for fabricated samples consistent with the present disclosure after undergoing the RTA process.

FIG. 6 is a graph comparing the PL Intensity (log scale) versus bandgap energy for fabricated samples consistent with the present disclosure.

FIG. 7 is a comparison of data obtained with photoluminescence with the theoretical predictions for fabricated samples consistent with the present disclosure.

FIG. 8a is a graph of the index of refraction versus bandgap energy for fabricated samples consistent with the present disclosure.

FIG. 8b is a graph of the extinction coefficient for a fabricated sample consistent with the present disclosure.

FIG. 9 is a graph of the absorption coefficient for a fabricated sample consistent with the present disclosure extracted from ellipsometry analysis.

FIG. 10 is a graph of the evolution of the fundamental confined transition energy of the quantum well (mj=±½ hole level to 1st electron level) for GaAsN on GaAs as a function of nitrogen composition for 4 nm (top line), 6 nm (middle line) and 8 nm (bottom line) thick wells. The dotted line is for eye guidance and indicates the 1 eV threshold. Estimated N compositions in the alloy are recorded.

FIG. 11 shows the calculated absorption coefficient for bulk GaAs (right-hand line), 6 nm thick GaAs0.971N0.029 Quantum Well without thermal broadening (middle line), and the overall absorption of a single quantum well (including excitonic absorption and thermal broadening) at 300K (left-hand line).

FIG. 12 shows the Internal Quantum Efficiency of a p-i-n GaAs Solar Cell where 10 period GaAs_{0.971}N_{0.029} (6 nm) and GaAs (15 nm) MQW is inserted in the i-region (solid lines) and comparison with a device made without a MQW region (broken lines). The shaded area highlights the contribution of the quantum well region.

FIG. 13 shows the evolution of the short circuit current response as a function of the number of quantum wells of a p-i-n MQW GaAs/GaAs_{0.968}N_{0.032} behind a 2.5 μm GaAs (1.42 eV) solar cell with 6 nm thick GaAsN quantum wells and 15 nm GaAs barriers.

FIG. 14 shows efficiency vs. number of quantum wells using experimentally determined GaAsN absorption coefficient for a p/n InGaP(1.8 eV, 2.3 micron), p-i-n MQW GaAs/GaAsN(1.1 eV, 5.3 microns+i-region) and Ge (0.66 eV, 3.3 microns) triple junction solar cell with quasi-ideal diffusion lengths. A flat 2% reflection loss is considered for the entire range of the spectrum. The calculation is implemented for 1 sun AM0 (sunlight in outer earth atmosphere) and 500 sun concentration under AM1 illumination.

FIG. 15 shows spectral response for solar cells consistent with the present disclosure.

FIG. 16 shows 1st, 2nd and 3rd electron confinement energies for a GaAsN well thickness of 6 nm, along with the valence band offsets for the holes of quantum wells consistent with the present disclosure.

FIG. 17 shows the calculated absorption coefficient of 4 nm-thick GaAsN single quantum well showing the improvement in absorption in (i) bulk GaAs,(ii) GaAs0.966N0.034 Quantum Well without thermal broadening, and (iii) total performance including excitonic absorption at 300K with well width of 4 nm.

FIG. 18 shows AM0 efficiency and short circuit current of a 4 junction tandem solar cell, as a function of numbers of 4 nm QWs inserted in the the 3^{rd} subcell

FIG. 19 shows calculated Spectral Response of the 6 nm QW GaAsN solar cell compared with experimental solar cell data.

FIG. 20 shows variation of the confined energy levels with the inclusion of strain compensation (through inclusion of Sb in barriers). The dotted lines represent the strain compensated system, while the solid lines are the values without it.

FIG. 21 shows efficiency as a function of number of wells for AM1.5 D (1 sun and 500 sun) for triple junction InGaP(1.8 eV)/MQW(1.1 eV)/Ge (0.66 eV) consistent with the present disclosure using strain compensated GaAsN(6 nm)/GaAsSb (12 nm) multi-quantum wells.

FIG. 22 shows 1 sun illumination efficiency as a function of number of wells in the 4-junction configuration for AM0 and AM1.5 using strain compensated GaAsSb-GaAsN multi-quantum wells.

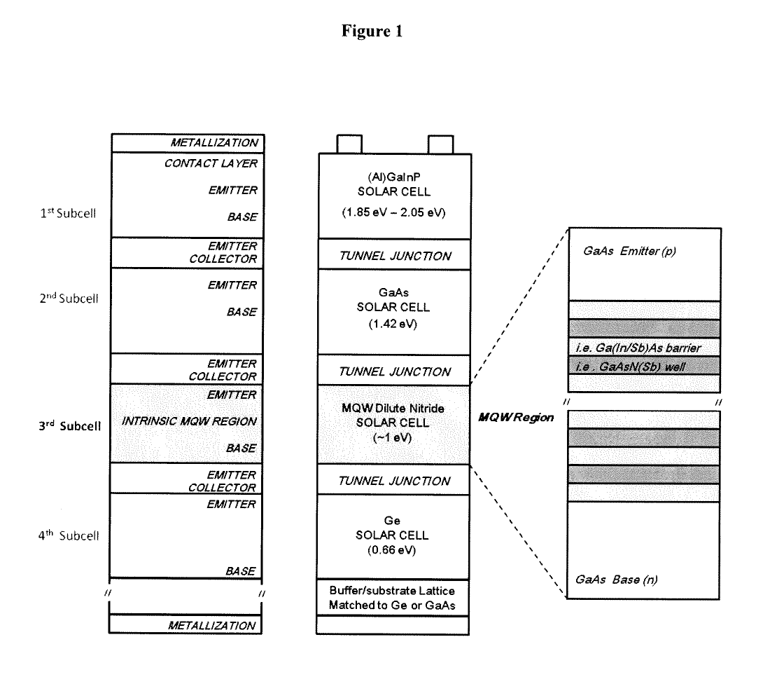

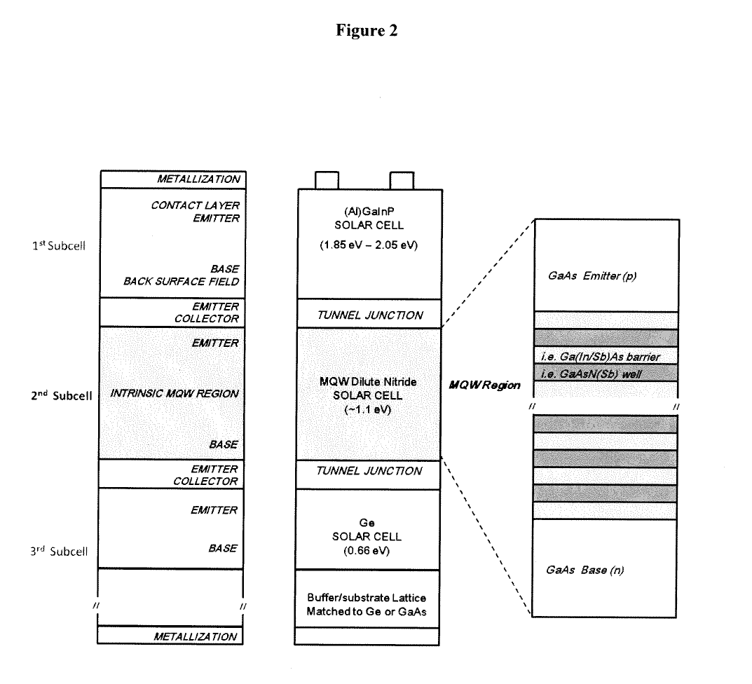

While the present invention is susceptible to various modifications and alternative forms, specific exemplary embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

The present disclosure relates to the design and fabrication of solar cells using GaAsN epilayers with room temperature bandgaps in the 0.9-1.2 eV range. In certain embodiments, dilute nitride (Ga(In)AsN) multi quantum wells are introduced to provide a bandgap in the range of 1 eV in between GaAs and Ge junctions of existing In(Al)GaP/GaAs/Ge multi-junction solar cells.

A “quantum well” is briefly defined as a heterostructure comprised of two or more semiconductor materials having different band gaps and where at least one of the semiconductor materials (the well material) has a smaller band gap than the largest band gap available in the combination and exhibits a thickness below about 20 nanometers (nm). The thickness of the larger band gap (barrier) material is not so critical, but in practice is generally below 100 nm. A carrier in the well region is subjected to a potential barrier arising from the presence of a wider band gap in the surrounding barrier material. This results in the quantization of energy states in the well, and these additional energy states may then absorb light having longer wavelength than that absorbed by the wide band gap material.

In some embodiments of the present invention, dilute nitride quantum wells may be used as a 3rd junction (i.e. apparent bandgap of 1 eV) in a (Al)InGaP (1.9 eV)/GaAs(1.42 eV)/MQW(1 eV)/Ge(0.66 eV) quadruple junction device. In other embodiments, the dilute nitride quantum wells may be used in triple junction configuration with a 1.1 eV MQW solar cell inserted between GaInP (1.8 eV) and Ge(0.66) subcells.

In certain other embodiments, the dilute nitride quantum wells may be used in conjunction with conventional solar cells. For instance, in certain conventional solar cells, small amounts of Indium (In) may be incorporated into a GaAs junction and its dilute nitride alloys on slightly mismatched substrates like Germanium. In other conventional cells, the GaAs junction may be replaced by strain-compensated barriers (i.e. inclusion of elements like Phosphorous, Aluminum, Antimony, Bismuth, and/or Indium in the barrier material) in the quantum well region as described by in U.S. Pat. No. 5,851,310, Freundlich et al, which is fully incorporated herein by reference. In certain other embodiments, small amounts of Indium or Antimony may be included in the GaAsN junction. As will be appreciated by those of ordinary skill in the art with the benefit of the present disclosure, the dilute nitride quantum wells may be used in conjunction with these conventional solar cells.

In some embodiments of the present disclosure MQW (Multiple Quantum Well) made of GaAsN 1 eV subcells may produce photocurrents in excess of 18 mA/cm⁻² when operating in a tandem configuration behind a GaAs solar cell. These embodiments may be capable of supporting a four junction solar cell with 1 sun conversion efficiency of approximately 40%.

The suitability of dilute nitride quantum wells in a particular solar cell application may be assessed using the framework of 10 band k.p model (E.O. Kane Physics of III-V Compounds, 1966; Shan W Band anticrossing in GaInNAs alloys, 1999). In that framework, the confined fundamental and excited energy states of electrons and holes, as well as absorption properties of strained and lattice matched (In)GaAsN/GaAs quantum wells are extracted as a function of nitrogen content, quantum well thickness, and the number of periods. The model accounts for strain, the spin-orbit split-off and N-induced band anti-crossing. A transfer matrix method is used to predict electron and hole confinement energy levels and the optical absorption of (In)GaAsN/GaAs quantum wells and accounts for excitonic absorptions in the wells. These parameters may be used to calculate illuminated current vs. voltage characteristics (IV) and external quantum efficiency of the proposed quantum well solar cells. While not wishing to be bound by theory, it is believed that because of strong photoabsorption properties, these MQW 1 eV subcells can produce photocurrents in excess of 18 mA/cm⁻² when operating in a tandem configuration behind a GaAs solar cell, and thus may be capable of supporting a four junction solar cell with 1 sun airmass 0 (AM0) conversion efficiency of approximately 40%.

In another embodiment, high quality GaAsN epilayers with bandgaps in the desired 1 eV range (Eg(300K): 0.93-1.18 eV) are produced. Fully pseudomorphic layers of GaAsN (3.7%) with thicknesses in excess of 120 nm are possible because of the relaxation properties thereof. This allows for incorporation of more than 20 to 25 periods of MQWs. In some embodiments, up to 100 periods could be incorporated. In some alternative embodiments, small amounts of Indium or/and Antimony (or thin layers of material made in a InGaAsNSb material system) may be incorporated in the GaAsN quantum wells or barriers to engineer the strain in the quantum well region. This may allow incorporation of a larger number of quantum wells. In order to assess the suitability of GaAsN quantum wells for a particular four-junction tandem operation, a model of the photocurrent response may be used. In certain embodiments, a 20 to 25-period MQW may be sufficient for the sub-cell to meet the current matching requirements under air mass zero (AM0) conditions. In one embodiment, a GaAsN (1.1 eV) MQW device for operation in a GaInP (1.8 eV)/MQW/Ge(0.66 eV) configuration, a middle cell with about 30 GaAsN 6 nm wells may achieve 500 AM1.5 suns efficiencies in of excess 48%, or a 1 sun AM1.5 efficiency of approximately 36%.

Another embodiment of the present invention discloses the fabrication and characterization of GaAsN quantum wells with a low transient N injector and their use in Multiple Quantum Wells (MQW) solar cells. Results obtained on GaAsN MQW show that PL linewidths lower than 20 meV obtained without a run-vent system can be achieved.

In certain embodiments of the present invention, the incorporation of a simple valve-controlled Run-Vent system could be used to circumvent the need for the N-doped GaAs buffer in the fabrication of the currently disclosed MQW devices.

Another embodiment of this invention discloses the photoluminescence (PL) characteristics and the effect of rapid thermal annealing (RTA) process on fabricated GaAsN samples. For as-grown samples with N content higher than 2%, the photoluminescence signal is dominated by the GaAs band-edge luminescence and a merely detectable PL signal is observable in the expected luminescence range of dilute nitride alloy, suggesting degraded optical properties (a common observation for dilute nitride alloys). However, the optical quality of the grown epilayers is significantly improved when the samples are subjected to a RTA process.

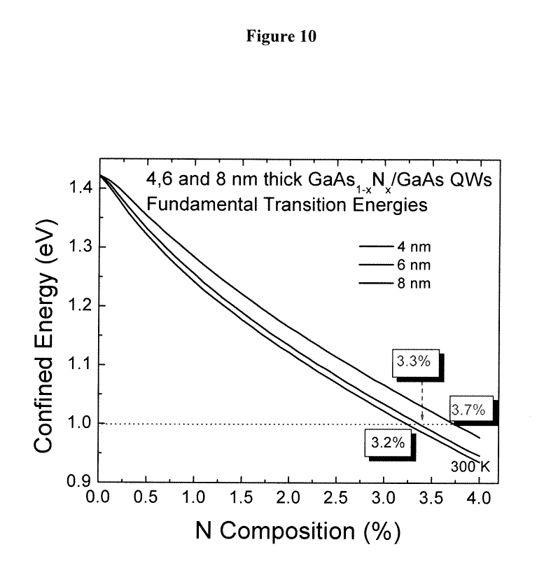

Another embodiment of the present invention discloses a model to predict the behavior of Multiple Quantum Wells solar cells by modeling the energy of confined states in GaAsN quantum wells. An evaluation based on fabricated samples suggests possibilities for the synthesis of fully pseudomorphic layers of GaAsN (3.7%) with thicknesses in excess of 120 nm. This suggests the possibility of incorporating a very large number of quantum wells of GaAsN (>20 periods) without the need to incorporate In or Sb in the wells or incorporation of strain compensation layers. The band structures of GaAsN/GaAs are calculated within the framework of the k.p formalism that accounts for spin-orbit couplings, strain effects, and band anti-crossing effects of nitrogen (N) incorporation on the conduction band. The quantum mechanical treatment of the problem consists of solving the Schrodinger's equation of the movement of the electron. A transfer matrix method is used to predict the electron, heavy hole and light hole confinement energies. An example of the results obtained with such calculation for the evolution of the fundamental bandgap (1^{st} electron to 1 ^{st} heavy hole, i.e. hh, state) of quantum wells is provided in FIG. 10 where the quantum well confined energy (E±½) for GaAsN on GaAs as a function of nitrogen composition for 4 nm (black), 6 nm (red) and 8 nm (green) thick wells are shown. The dotted line is for eye guidance and indicates the 1 eV threshold. Also estimated N compositions are recorded. The model disclosed herein allows the extraction of confined fundamental and excited energy states of electrons and holes, as well as absorption properties of GaAsN/GaAs quantum wells as a function of nitrogen content and well thickness.

Another embodiment of the present invention discloses the modeling of the absorption coefficients of GaAsN quantum wells. The optical absorption of the quantum well region is extracted using:

$${α}_{QW} = \frac{4 {πe}^{2}}{{m}_{e}^{2} c ω L} {( ɛ \cdot {p}_{cv} )}^{2} \frac{{μ}_{h , l}}{ℏ} {\sum }_{k} Θ ( ℏω - {E}_{g} - \frac{{k}^{2} {π}^{2} {ℏ}^{2}}{2 {μ}_{h , l} {L}^{2}} )$$

$${α}_{Bulk} = \frac{2 {{e}^{2} ( ɛ \cdot {p}_{cv} )}^{2}}{{m}_{e}^{2} c ω} {( \frac{2 {μ}_{h , l}}{ℏ} )}^{\frac{3}{2}} {( ℏω - {E}_{g} )}^{\frac{1}{2}}$$

$${α}_{exc ( n , m )} = \frac{4 {πe}^{2}}{{m}_{e}^{2} c ω n} {( ɛ \cdot {p}_{cv} )}^{2} {\sum }_{n} {α}_{n} δ ( ℏω - {E}_{g} )$$

where ε.P_{cv} is the momentum matrix element between bulk conduction and valence bands, μ_{h,l} refers to the reduced effective masses for heavy and light holes, L is the length of the quantum well, ω is the angular frequency of the incoming radiation, E_{g} is the band gap of the relevant species, n is the refractive index of the solar cell material, and αₙ is the strength of the absorption Θ refers to the Heaviside function. It should be noted that here the availability of larger joint-density of states in the wells, as afforded by higher electron effective masses, warrants stronger absorption coefficient for these nanostructures. In the calculations, to account for the effect of a finite temperature T, the Heaviside function has been replaced by the Fermi distribution:

$${α}_{QW} = \frac{4 {πe}^{2}}{{m}_{e}^{2} c ω L} {( ɛ \cdot {p}_{cv} )}^{2} \frac{{μ}_{h , l}}{ℏ} {\sum }_{k} \frac{1}{1 + exp ( {E}_{g} + \frac{{k}^{2} {π}^{2} {ℏ}^{2}}{2 {μ}_{h , l} {L}^{2}} - ℏω / {k}_{B} T )}$$

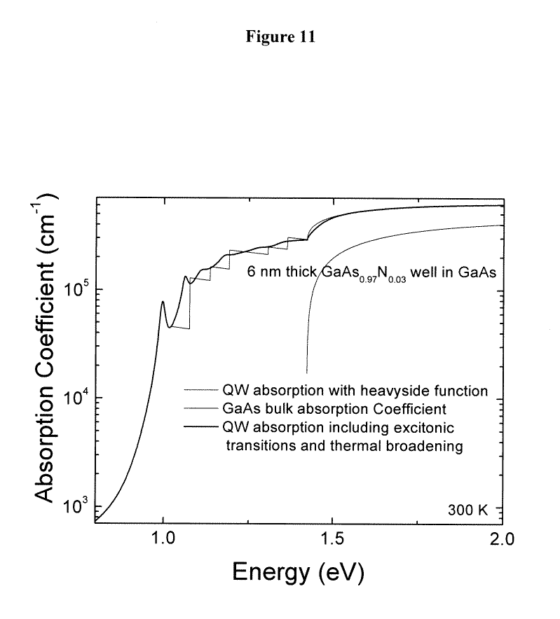

The calculated absorption coefficient (per cm) of a single 6 nm thick GaAsN quantum well is as shown in the FIG. 11. The response of a GaAs bulk is also shown in that figure for reference. The results show that the introduction of quantum well can be used to extend the calculated absorption response up to 1 eV while the overall above bandgap absorption is enhanced. The addition of the excitonic effect also leads to an overall enhancement of the absorption spectrum.

Another embodiment of the present invention discloses a method to evaluate the suitability of MQW solar cells made with GaAsN/GaAs wells for operation as either a 3^{rd} junction (1 eV) in a (Al)InGaP 1.9 eV)/GaAs(1.42 eV)/MQW1 eV/Ge(0.66 eV) quadruple junction tandem or as a triple junction configuration with a 1.1 eV MQW between GaInP (1.8 eV) and Ge(0.66).

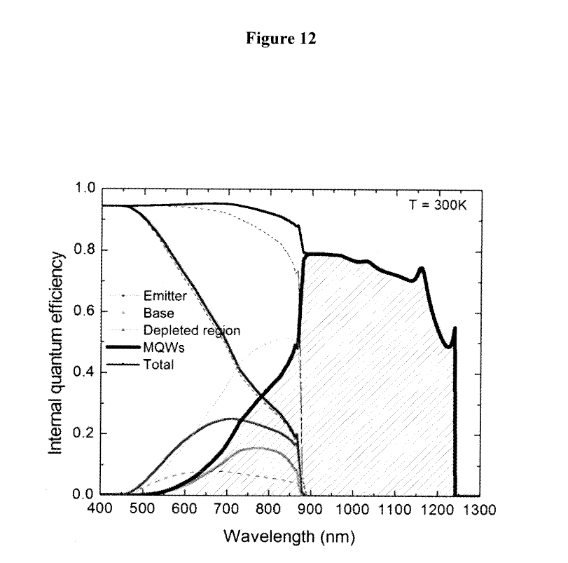

Using a modeling software for the Quantum Well Solar Cell (QWSC) previously developed at the University of Houston, we included the absorption coefficient (as calculated above) to estimate the short circuit current and IV characteristics of a 1 eV dilute nitride QWSC at AM0 conditions. The carrier escape is assumed to be thermoionic in nature and the escape probability is assumed to be equal to unity. Moreover, a conservative assumption of the electron effective mass is made for the GaAsN layer taken at 0.1 m_{c}. An example of the projected internal quantum efficiency calculated for 10 period GaAsN(6 nm)/GaAs (15 nm) MQW inserted between a 0.3 micron p-emitter (10¹⁸ cm-3) and 2 micron-base (4×10¹⁷ cm-3) solar cell is given in FIG. 12 and is compared to that obtained with a conventional solar cell (broken lines). The shaded area corresponds to the contribution of the quantum well region. These results show that the device comprising a MQW region made with 10 period of 4 nm-thick GaAsN (N composition 3.7%) wells and 15 nm-thick GaAs barriers exhibits a very strong photoresponse below the bandgap of GaAs. The unusually strong photoresponse is found to be consistent with the experimental work on the development of 1.15 eV dilute nitride quantum wells where a 15-period 6 nm wells of GaAsN with N˜1.8% resulted in quantum efficiencies in excess of 50% for the MQW region. The increase of the electron effective masses associated with larger N contents (3%-4%) results in even stronger below bandgap photoconversion.

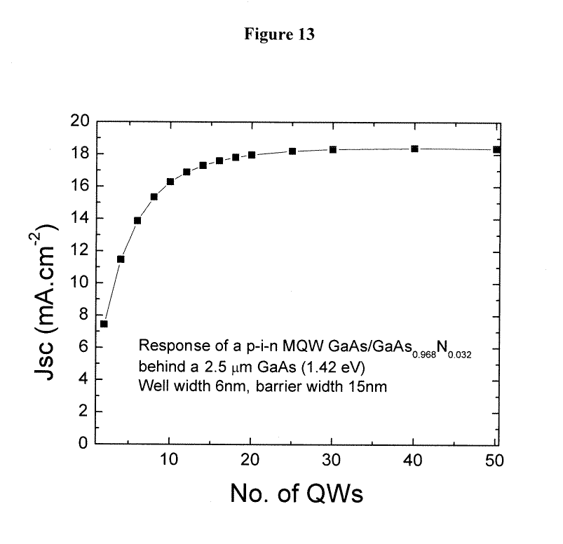

Another embodiment of the present invention discloses the effect of the number of quantum wells on the short circuit current response, particularly the evolution of the short circuit current response of a p-i-n MQW GaAs/GaAs_{0.968}N_{0.032} behind a 2.5 μm GaAs (1.42 eV) with 6 nm thick wells and 15 nm barriers. FIG. 13 shows that the current is increasing with increasing number of wells up to a point where most photons between the band gap of the QW SC (1 eV) and the one of GaAs (1.42 eV) are harvested. The current matching condition is projected to be reached for about 20-25 periods of Quantum Wells in the device intrinsic region (FIG. 13).

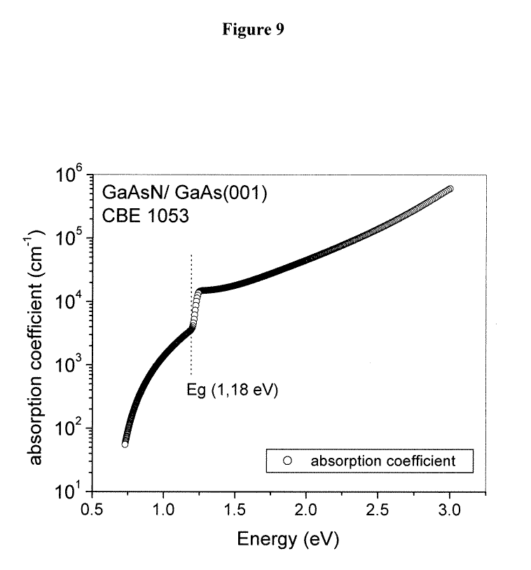

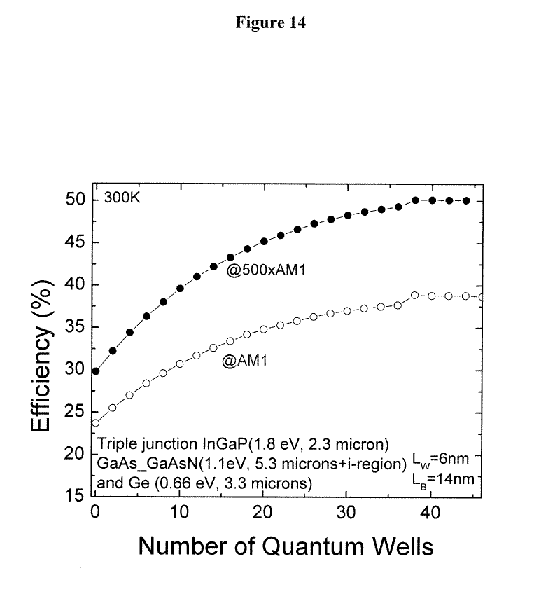

Another embodiment of the present invention discloses the effect of the number of quantum wells on the efficiency of a triple junction cells with GaAsN/GaAs MQW middle cell. The experimental absorption coefficient, adjusted for a threshold of 1.1 eV, is used to evaluate the performance of a p/n InGaP(1.8 eV, 2.3 micron), p(2×10¹⁸)-i-n(4×10¹⁷) MQW GaAs/GaAsN(1.1 eV, 5.3 microns+i-region) and Ge (0.66 eV, 3.3 microns) triple junction solar cell with quasi-ideal diffusion lengths. FIG. 14 provides the efficiency as a function of the number of quantum wells. Here the absorption coefficients in GaAsN are extrapolated from experimental absorption coefficients measured in FIG. 9. The calculation assumes a 2% reflection loss over the entire range of the device spectral sensitivity. It shows that under 1 sun and 500 suns respectively, and for an air mass of AM1, it is possible to reach photo-conversion efficiencies in excess of 36% and 48%, respectively.

The present invention relates to the modeling and fabrication of high quality pseudomorphic GaAsN quantum wells with bandgaps in the desired 1 eV range (room temperature gaps of 0.9-1.15 eV) and nitrogen concentrations up to 3.7% for the fabrication of a new type of solar cells. Despite the absence of the run-vent system (known to be critical to avoid GaAs barrier contaminations) the optimization of the Rapid Thermal Annealing (RTA) process allows for the formation of GaAsN epilayers with strong photoluminescence signals (comparable to that of high quality GaAs epilayers) and with photoluminescence (PL) linewidth lower than 20 meV. The study of the relaxation properties of GaAsN indicate possibilities for the fabrication of fully pseudomorphic layers of GaAsN (3.7%) with thicknesses in excess of 120 nm, suggesting possibilities of incorporating a large number of GaAsN quantum wells in GaAs In order to evaluate the suitability of GaAsN quantum wells for 4-junction tandem operation, a modeling of the photocurrent response as a function of the number of quantum wells is undertaken. The results show that the insertion of a GaAs p-i-n subcell where the i-region (sandwiched between the p and n conductivity layers) contains a Multiple Quantum Well made with 20-25 period of GaAsN/GaAs (i.e 6 nm GaAS0.₉₆₈N_{0.032} wells and 15 nm-thick GaAs wells) as a 3^{rd} junction in a 4 junction device (behind conventional GaAs subcell) provides sufficient current to fulfill the current matching requirements. As an example the device as devised here would deliver efficiencies in excess of 40% under typical sunlight illumination in space (1 sun AM0) and much higher efficiencies would be afforded under concentrated sunlight. The suitability of a GaAsN (1.1 eV) MQW device for operation in a GaInP (1.8 eV)/MQW/Ge(0.66 eV) configuration is also assessed and the results show that a middle cell with about 30 GaAsN 6 nm wells may achieve practical 500 suns (1 sun) efficiencies in excess of 48% (36%).

While the invention described here specifically focuses on a novel method to design and fabricate 1 eV solar cells using GaAsN epilayers with bandgaps in the desired range for the above mentioned triple and quadruple junction solar cell design (Eg(300K): 0.93-1.18 eV), one of ordinary skills in the art, with the benefit of this disclosure, would recognize the extension of the approach to other types of quantum well solar cells.

### EXAMPLES

### Example 1

A 0.9-1 eV GaAsN material was fabricated. A set of samples was grown by chemical beam epitaxy (CBE) in a Riber CBE32™ system. All samples are mounted In-free. After thermal desorption of the oxide at 590° C., a 200 nm GaAs buffer was grown at 520° C. Tri-ethylgallium (TEG) and arsine (AsH₃) are used as growth precursors. An epi nitrogen plasma injector is used to deliver reactive nitrogen species to the substrate. TEG was introduced in the reaction chamber via a low temperature organometallic injector maintained at about 120° C. to prevent precursor condensation in the injector. Arsine, prior to delivery to the reaction chamber, was thermally pre-cracked into mainly AsH and Asₑ reactive species using a high temperature hydride injector maintained at above 900° C. during the growth process. The growth of GaAs at 520° C. was performed in As-reach conditions and yielded a 2×4 surface reconstruction as checked by reflection high energy electron diffraction (RHEED).

After the growth of the buffer layer, the temperature was lowered to 445° C. under pre-cracked arsine flux. Upon reaching 445° C., the GaAs growth resumed at a rate of 1 molecular monolayer/sec (˜1 micron/hour). The nitrogen plasma was ignited during the GaAs buffer growth with the plasma source shutter closed. The plasma flow was adjusted to 1 sccm, and, upon stabilization of the flow, (approximately 2-3 minutes, as monitored through N partial pressure in the chamber), the Nitrogen shutter was opened and GaAsN was deposited. In the absence of run-vent N-system, the growth of GaAs with N-shutter closed (but plasma on) resulted in the formation of an N-doped GaAs sample with N content of ˜0.5%. The thickness of this intermediate buffer was about 40-50 nm.

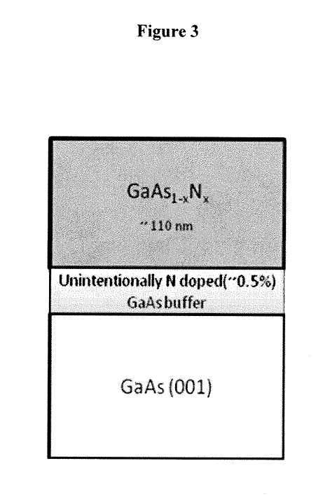

The thickness of the GaAsN epilayers was set to about 120 nm. Several samples were fabricated with the plasma power ranging from 300-600 W. A schematic representation of the fabricated samples is presented in FIG. 3. During the growth, 2×4 RHEED indicative of highly ordered surface morphology were recorded for all samples. Post growth, all samples exhibited a specular morphology.

### Example 2

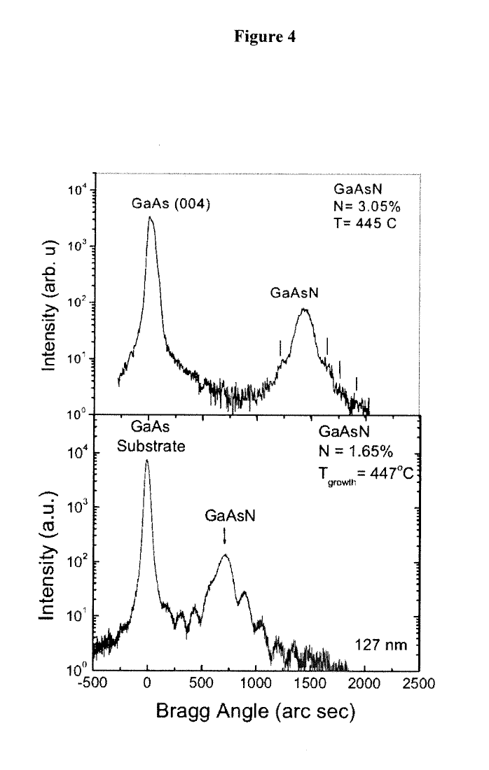

The content of substitutional nitrogen composition in the top epilayer of the GaAsN layer of two of the samples from Example 1 were extracted from high resolution X-ray diffraction analysis. The diffraction patterns also allow measurement of the composition and thickness of the epilayer from the period of pendellosung interference fringes. An example of (400) rocking curves recorded in the vicinity of GaAs substrate peak for two samples with different nitrogen compositions is shown in FIG. 4. The upper curve has a nitrogen composition of 3.05%, whereas the bottom curve has a nitrogen composition of 1.65%. The periodicity of the pendellosung fringes is consistent with the targeted ˜120 nm epilayer thickness.

### Example 3

Compositions extracted from X-ray analysis for samples fabricated in Example 1 shown below in Table 1. In each of the samples, the growth rate was fixed at 1M/sec at a temperature of 445° C. and with a GaAsN layer of approximately 120 nm in thickness. Table 1 further includes the plasma powers, the 10 K photoluminescence (PL) peak positions and expected room temperature (300 K) bandgaps extracted from band-anti-crossing (BAC) analysis.

TABLE 1
Compositions extracted from X-ray analysis for samples CBE1046, CBE1047, CBE1050, CBE1052,
CBE1053, and CBE1056.

| | | Growth | | | | E_{1/2} | Eg_{1/2} |
|---|---|---|---|---|---|---|---|
| | | Temp. ° C. | Plasma power | Thickness | N content % | (10K) | (300K) |
| | Growth rate | (Tc) | (W) | (nm) | (XRD) | PL | BAC-model |
| CBE1046 | 1 M/sec | 445 | 400 | ~120 | 3.05 | — | 1.04 |
| CBE1047 | 1 M/sec | 445 | 400+H | ~120 | 2.61 | — | 1.07 |
| CBE1050 | 1 M/sec | 445 | 300+H | ~120 | 3.10 | 1.13 | 1.03 |
| CBE1052 | 1 M/sec | 445 | 600 | ~120 | 1.81 | — | 1.10 |
| CBE1053 | 1 M/sec | 445 | 600+H | ~120 | 1.44 | 1.27 | 1.18 |
| CBE1056 | 1 M/sec | 445 | 300 | ~120 | 3.70 | 1.03 | 0.93 |

### Example 4

The RTA process was used on three of the samples fabricated in Example 1. In a nitrogen environment, each of the three samples was sandwiched between two GaAs wafers. The sandwiched samples were rapidly exposed to infra radiation that yielded substrate temperatures ranging from 700 to 830° C. A separate sample from fabricated in Example 1 was kept as a control sample.

XRD and photoluminescence characteristics were recorded prior to and after RTA. For the samples that underwent the RTA process, exposures up to T=800° C. produced no noticeable change in the XRD. Evolution of the in-plane and orthogonal components of the lattice constant as extracted from asymmetric and symmetric XRD analysis indicated that GaAsN epilayers were fully strained and under biaxial compressive strain. For samples with higher Nitrogen composition, typically between 3% and 3.7%, an RTA of 30 sec at 800° C. yielded the best results and a strong excitonic PL signal was recorded.

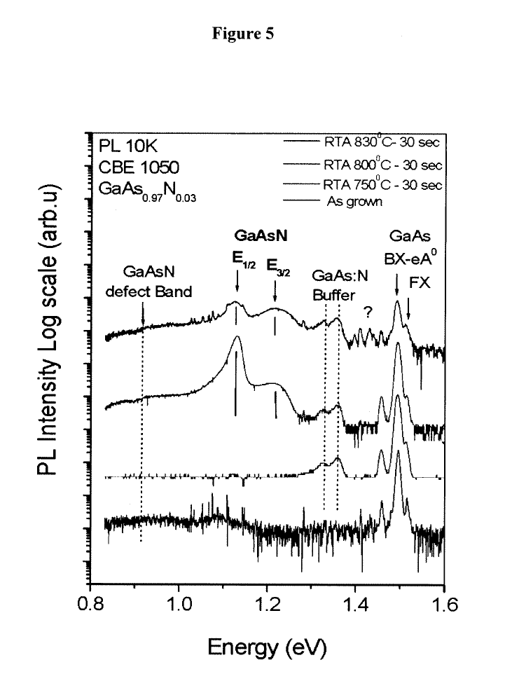

FIG. 5 shows the evolution of the photoluminescence signal for sample 1050 (as shown above in Table 1) at various temperatures. As shown in FIG. 5, strain induced split E_{1/2} (1.13 eV) and E_{3/2} (1.21 eV) GaAsN excitons were visible after RTA at 800° C. As further shown in FIG. 5, weak excitonic bands corresponding to the PL response of nitrogen-contaminated-GaAs buffer at 1.33 eV and 1.36 eV were visible for RTA higher than 750° C.

As further shown in FIG. 5, a degradation of near band-edge GaAs and GaAsN PL is present when the RTA process is performed at temperatures higher than 830° C. Unexpectedly, when the RTA process was performed 30 sec at 800° C. conditions, the photoluminescence signal was improved by three orders of magnitude and became comparable to that of the high quality GaAs. Further, despite fluctuations in the composition of the alloy associated with the nitrogen transients PL full width at half maximum (FWHM) of about 20 meV were recorded for GaAsN epilayers.

### Example 5

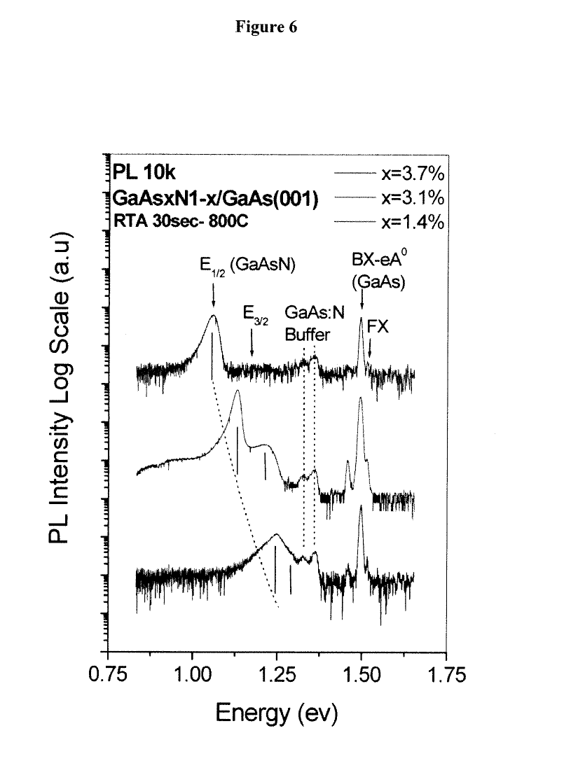

In Example 5, the bandgap of GaAsN versus the nitrogen concentration was examined. In FIG. 6, the PL spectra for samples with various nitrogen concentrations fabricated in Example 1 were subjected to the RTA process for 30 sec at 800° C. in GaAs1-xNx (120 nm)/GaAs(001) epi-structures. The expected E_{±1/2} and E_{±3/2} positions of the GaAsN strain induced split bandgaps shift to from 1.00 eV to 1.25 eV at 10K, and 0.9 to 1.15 eV at room temperature, with higher nitrogen content.

### Example 6

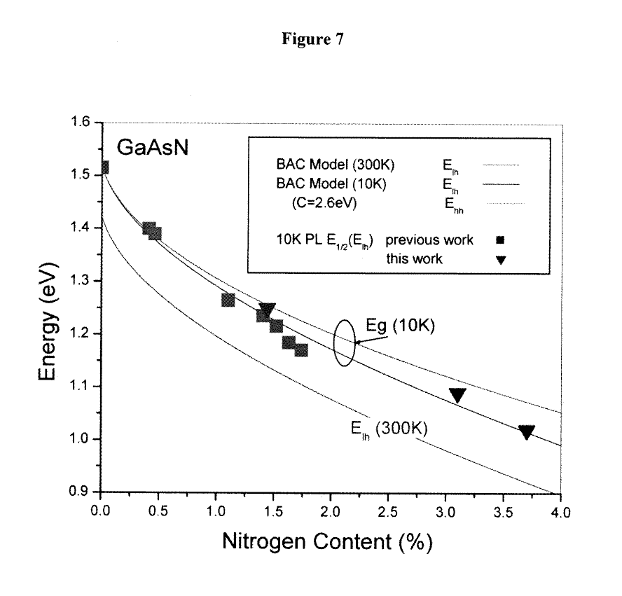

Based on the information obtained in Example 5, projected room temperature bandgap positions as extracted from BAC in Table 1 were calculated. FIG. 7 shows a comparison of the data obtained from photoluminescence in Example 5 with the theoretical predictions based on a BAC model, where a coupling coefficient between localized N-states and the conduction band of GaAs of C=2.6 eV was accounted for. The modeling further accounts for the biaxial tensile stress in GaAsN epilayers. The band in FIG. 7 bands are referred to by the hole masses in the normal direction: light holes (Eₗₕ) and heavy holes(Eₕₕ) respectively.

### Example 7

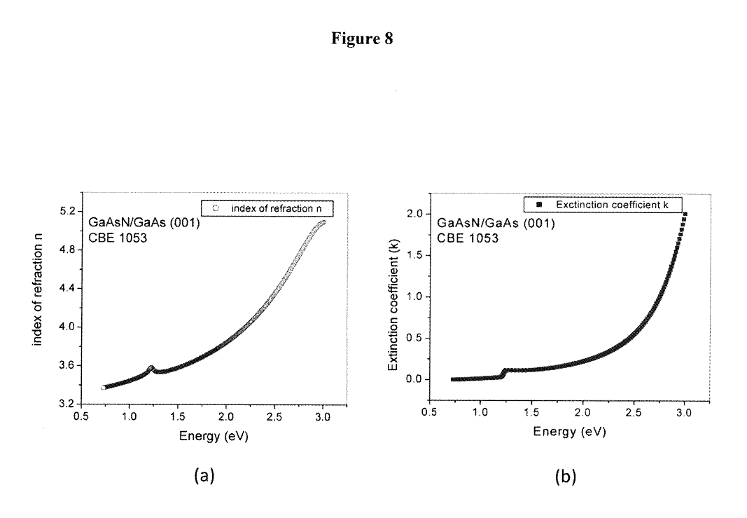

An ellipsometry analysis of sample 1053 fabricated in Example 1 was performed. FIG. 8 shows spectroscopic ellipsometry data (Index of refraction vs. Energy) obtained at room temperature for a GaAsN epilayer in sample 1053 (Eg at 300K˜1.18 eV). As shown in FIG. 8, the bandgap value extracted from n and k singularities is consistent with that estimated from the BAC calculations shown in FIG. 7. FIG. 8 further shows that the absorption coefficient is significantly stronger in GaAsN than in GaAs. It is expected that, due to the increase of electron effective masses, stronger absorption coefficients would be obtained at higher nitrogen compositions. FIG. 9 shows the absorption coefficient extracted from n,k analysis, which is consistent with the BAC model predictions.

### Example 8

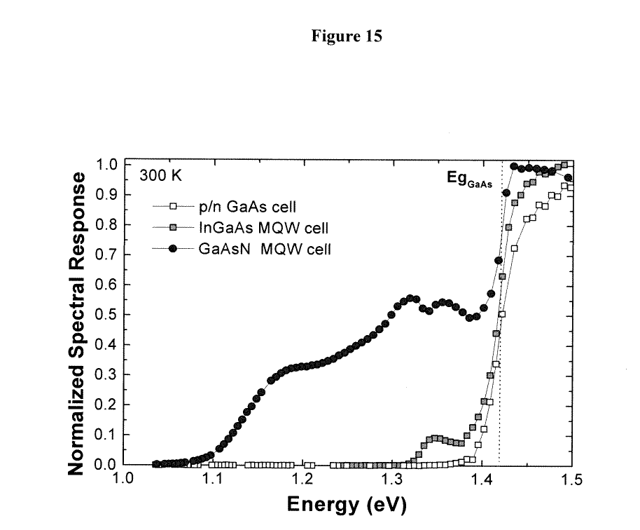

The efficiency and spectral response of 1 eV solar cells where dilute nitride quantum wells are inserted within the intrinsic region of a conventional p-i-n GaAs solar cell was modeled. In addition to an increase in absorption due to the introduction of energy states below the bandgap, the increase in the electron effective mass to up to 0.1 mₑ in dilute nitrides is expected to further increase the absorption. This behavior is seen in the experimental data where spectral response of the above design (annealed, as shown in FIG. 15), shows the vastly increased absorption of dilute nitride QW as opposed to InAs.

The modeling of the proposed structure was done by first calculating the band structure of the dilute nitrides via k.p formalism, and the confined fundamental and excited energy states of electrons and holes, via the transfer matrix method. The optical absorption due to the bulk region, the quantum well region and the excitonic excitations are incorporated in the calculations for the absorption coefficient, which is then used to estimate the spectral response, internal quantum efficiency (QE), IV characteristics and photo-conversion efficiency of the solar cells. These are then compared with the theoretical limit of 42% under AM0 which has been predicted, with the photocurrent output of 18 mA/cm⁻² and 52% under 500 suns concentration.

### I. Theoretical Model

### A. Band Structure Calculation

The effect of decrease in bandgap due to the incorporation of N species into the bulk GaAs structure has been described by the Band Anti-crossing Model (BAC) where localized resonant states of nitrogen couple with the conduction band of the bulk crystal, giving rise to a shift in the conduction band energy, with the lower level corresponding to the reduced bandgap. The band structures of GaAsN were hence calculated by including the band anticrossing effects of N incorporation on the conduction band, along with spin-orbit couplings and strain effects.

The transfer matrix approach for calculation of confinement energies consists of solving the Schrodinger equation for the quantum well, and then matching boundary conditions in order to obtain the effect of each well. To this calculation, two additional constraints have to be added, with regard to the effect of the incorporation of nitrogen, as well as due to the strain resulting from the same. According to the 10 band k.p model, which includes the contribution of the 8 band Kane model along with the contribution of the resonant states, the energies of the sub-band created by the introduction of the nitrogen are (at k=0):

$$\begin{matrix}{E}_{\pm } ( x , P ) = \frac{1}{2} ( {E}_{N} + {E}_{c} \pm \sqrt{{( {E}_{N} - {E}_{c} )}^{2} + 4 {V}^{2}} ) & ( 1 ) \\ {E}_{N} ( x , P ) = {E}_{N 0} - γ x + {α}_{N} P & ( 2 ) \\ {E}_{c} ( x , P ) = {E}_{c 0} - α x + {a}_{c} P & ( 3 )\end{matrix}$$

For GaAsN, E_{N} has a value of 1.65 eV and the value of V=2.6 eV gives a reasonably good fit.

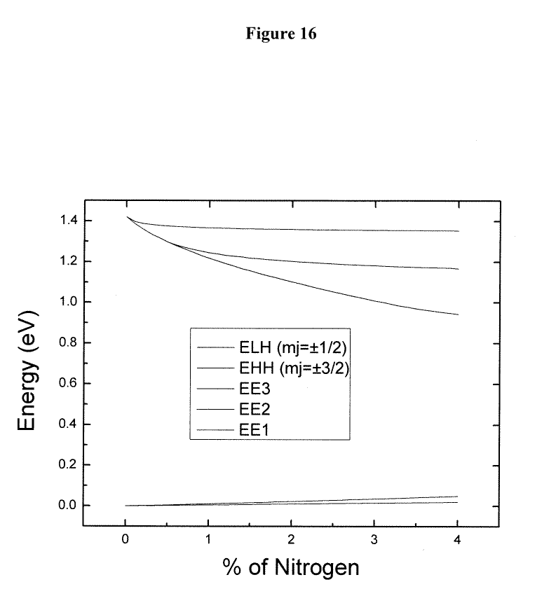

Due to a hydrostatic potential, there is an induced strain in the structure, and hence a shift in the positions of the conduction band and the valence band. The equations for strain effect include the hydrostatic potential effects as well as the effect of spin-orbit coupling. The strain is in the plane of the quantum well, and hence the energy of the p-orbital would be raised, and the symmetric s-orbitals would be unaffected. This would hence give a raising of the mⱼ=±1/2 level, which we refer to here as light hole, with respect to the mⱼ±3/2, which is referred to as the heavy hole. FIG. 16 gives the observed variation of the confinement energies of the electrons as well as the valence band offsets for the light hole and heavy hole respectively. As it can be seen, the hole energy separation is very small when compared to the energy scales of the transitions from the valence to the conduction band.

### B. Absorption Coefficient

Optical absorption has contributions from the quantum well region, the bulk crystal, as well as the absorption due to excitons. For calculating the possible transitions for the electrons, heavy holes and light holes confined in the quantum wells, the energies were calculated using the transfer matrix approach as explained in the previous subsection. From the value of the transition energies, the density of states for the levels, and consequently the absorption between any two levels, the total absorption coefficient is then calculated.

The absorption of the quantum wells was also applied sequentially, in order to obtain the net effect from all the wells. The incoming photon flux for a subsequent well is attenuated by the distance travelled in the previous well, and also the barrier, so the net contribution to the absorption attenuates with distance as required.

In our calculations, a conservative approximation of electron effective mass=0.1 mₑ was used. Additionally, in the calculations, to account for the effect of a finite temperature T, the Heaviside function has been replaced by the Fermi distribution. Using this, the expressions for the optical absorption of the quantum well region, bulk region and excitonic effects are given by where the quantum well contribution is as shown in Equation 4.

$${α}_{QW} = \frac{4 {πe}^{2}}{{m}_{e}^{2} c ω L} {( ɛ• {p}_{cv} )}^{2} \frac{{μ}_{h , l}}{ℏ} {\sum }_{k} \frac{1}{1 + exp ( {E}_{g} + \frac{{k}^{2} {π}^{2} {ℏ}^{2}}{2 {μ}_{h , l} {L}^{2}} - ℏω / {k}_{B} T )} \qquad ( 4 )$$

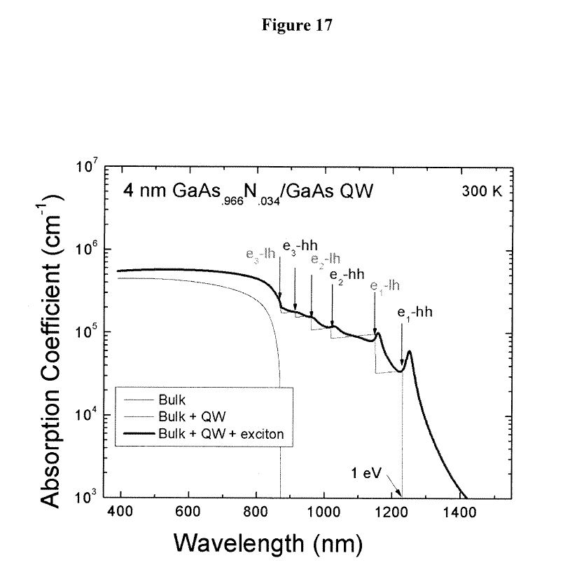

The absorption coefficient so obtained has been shown in FIG. 17.

### C. IV and Quantum Efficiency Calculations

Using a modeling software for the Quantum Well Solar Cell (QWSC) previously developed by the same group at the University of Houston, we included the absorption coefficient (as calculated above) to estimate the efficiency of the 1 eV dilute nitride QWSC at AM0 conditions. The assumptions are that the carrier escape is thermionic in nature and escape probability is equal to unity. The efficiency of this structure as incorporated into the intrinsic region of the GaAs sub-cell (behind the GaAs sub-cell of a multi-junction InGaP/GaAs/Ge solar cell) was then calculated by current matching. In this optimization, the number of quantum wells was varied to obtain the limit on the short circuit current.

### II. Results

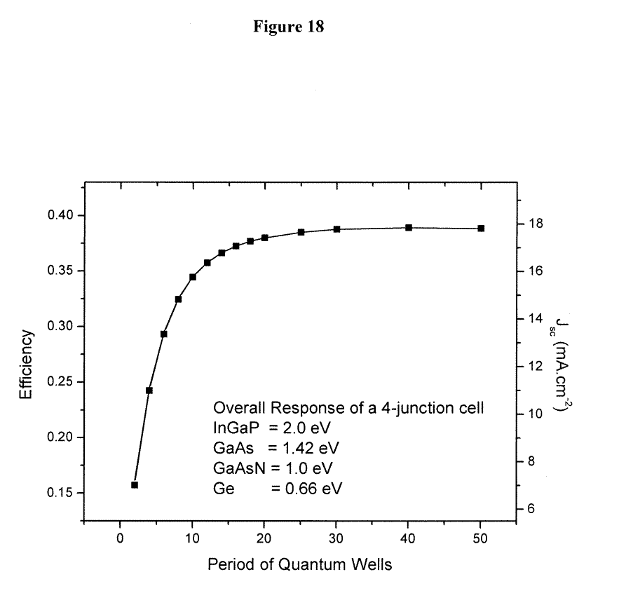

In order to verify the robustness of our model, it was applied to estimate the response as compared to a previously grown GaAsN solar cell (FIG. 15). One had to take into account the slight spread of the energy levels as they are not perfect wells with sharp boundaries when realistic growths are taken into account. There is no dip in the spectral response at 1.42 eV in the experimental curve as opposed to the theoretical calculations as the sample had been annealed before measurement. The calculations were also done for ˜1 eV absorption, as required for the 4 junction design, and the results are summarized in FIG. 18.

From the results, it can be seen that the comparison with experimental data, shows that the estimate of the efficiency is reasonable with respect to the parameters that we are using, and that the required current matching can be obtained in order to get the efficiency of the solar cell up to 40%.

### Example 9

As described herein, inserting quantum wells within the intrinsic region of a GaAs cell is a useful way of increasing sub bandgap photoconversion efficiency of the cell. With the thickness of the wells is lesser than the minority carrier diffusion length, it is possible to render the cell less sensitive to minority carrier properties. The increase in the electron effective mass of up to 0.1 mₑ in dilute nitrides is expected to further increase the absorption. The above design was modeled above, without however taking into account either the strain compensation or the effect of the electric field on the QW energy levels and hence the absorption.

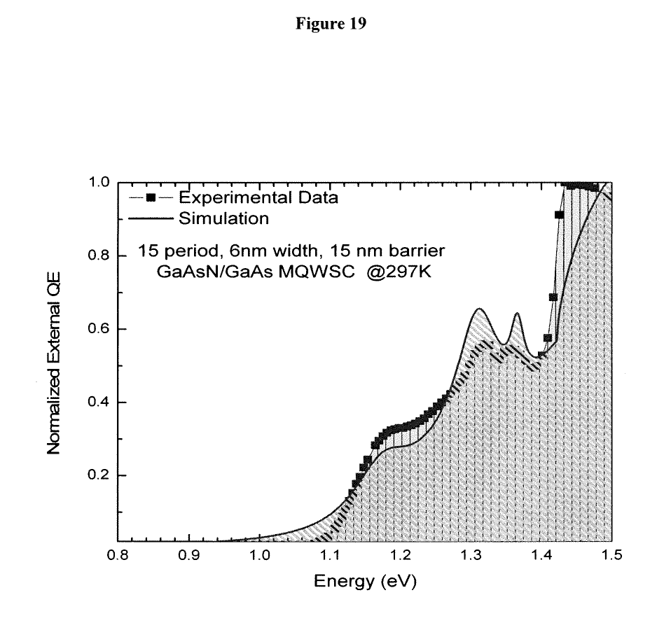

There is a possibility of the QW system relaxing due to the strain with an increase in the number of quantum wells, and strain compensation is a good way of overcoming that problem. In the present work, the strain balancing effect is hence taken into account, by including barriers of GaAsSb (or alternatively GaInAs) to offset the strain due to GaAsN. There is a variation of the absorption oscillator strength due to the electric field, which has also been included. The optical absorption due to the bulk region, the quantum well region and the excitonic excitations are incorporated in the calculations for the absorption coefficient. The absorption coefficient was fitted to the experimental data (FIG. 19) obtained in an earlier work on MQW solar cell (A. Freundlich 2007) and was hence used to estimate the spectral response, internal quantum efficiency (QE), IV characteristics and photo-conversion efficiency of the solar cell designs.

### Calculations

### Evaluation of Strain Compensation

In addition to the strain caused in the quantum wells, the strain of the opposite direction is induced in the barrier by utilizing GaAsSb (or GaInAs) as the Sb(In) atom is much larger than the N atom. The strain effects are evaluated by using the well known proportion:

EᵢαGᵢtⱼεᵢ²

Where Eᵢ refers to the energy of the layer, Gᵢ refers to the shear modulus of the iₜₕ layer, t is the thickness of the layer, and εᵢ is the strain. From this we obtain:

$$\frac{{t}_{i} {G}_{i}}{{t}_{ii} {G}_{ii}} = - \frac{{ɛ}_{ii}}{{ɛ}_{i}}$$

Where the relation between successive layer thicknesses are calculated. In our work, values of 12 nm for the barrier and a general range of 6 nm for the well were generally used.

### Band Structure Calculation

The effect of decrease in bandgap due to the incorporation of N species into the bulk GaAs structure has been described by the Band Anti-crossing Model (BAC) where localized resonant states of nitrogen couple with the conduction band of the bulk crystal, giving rise to a shift in the conduction band energy, with the lower level corresponding to the reduced bandgap. The band structures of GaAsN were hence calculated by including the band anticrossing effects of N incorporation on the conduction band, along with spin-orbit couplings and strain effects, both from the QW and the barrier.

The transfer matrix approach for calculation of confinement energies consists of solving the Schrodinger equation for the quantum well, and then matching boundary conditions in order to obtain the effect of each well. Due to a hydrostatic potential, there is an induced strain in the structure, and hence a shift in the positions of the conduction band and the valence band. The equations for strain effect include the hydrostatic potential effects as well as the effect of spin-orbit coupling. The strain is in the plane of the quantum well, and hence the energy of the p-orbital would be raised, and the symmetric s-orbitals would be unaffected. This would hence give a raising of the mj=±1/2 level, which we refer to here as light hole, with respect to the mj=±3/2, which is referred to as the heavy hole.

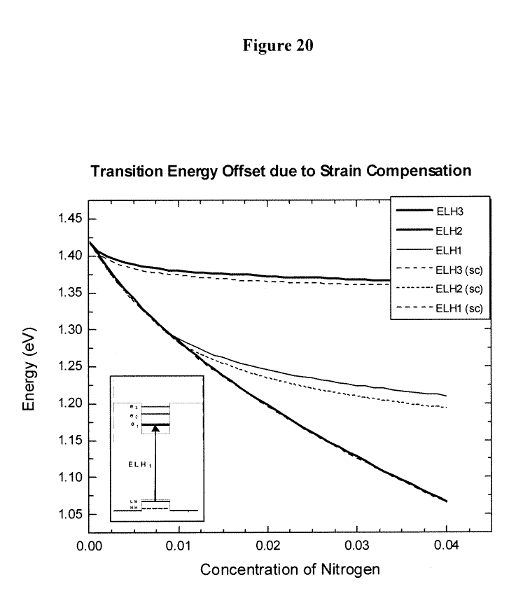

Incorporating the strain compensation in this model, the energy levels undergo a slight shift, which changes the transition energies as shown in FIG. 20. Furthermore, there is a continuum of possibilities for choosing the concentrations of Sb and N, which together create the strain compensation for the transition energy to be ˜1.1 eV. For every value of the concentration of N, the strain balancing was carried out according to equation (3) and the corresponding value of Sb-content was extracted.

### Effect of Electric Field on Oscillator Strength

The oscillator strength of the transition is required for the calculation of the absorption coefficient:

$${α}_{Bulk} = \frac{2 {e}^{2} {\vert ɛ \cdot {p}_{cv} \vert}^{2}}{{m}_{e}^{2} c ω} {( \frac{2 {μ}_{h , l}}{ℏ} )}^{\frac{3}{2}} {( ℏω - {E}_{g} )}^{\frac{1}{2}}$$

Here, |ε.p|² corresponds to the overlap of the wave functions, and it is expected that with the inclusion of the electric field within the QW region, the overlap would be varied. This behavior has been examined in the literature and a sharp decrease in the oscillator strength is expected as the width of the QW is increased. This reduction was taken into account while fitting the model to the experimental data of MQW, in order to extract the absorption coefficient.

### Results

It was seen that the Sb concentration of roughly 7% will compensate the strain of the dilute nitride QW. Utilizing the above confinement energies, the absorption coefficient was calculated, where the effect of the electric field on the oscillator strength of the resulting absorption was also taken into account. This calculation was used in the calculation of the spectral response to be compared with the experimental data obtained for QW grown earlier.

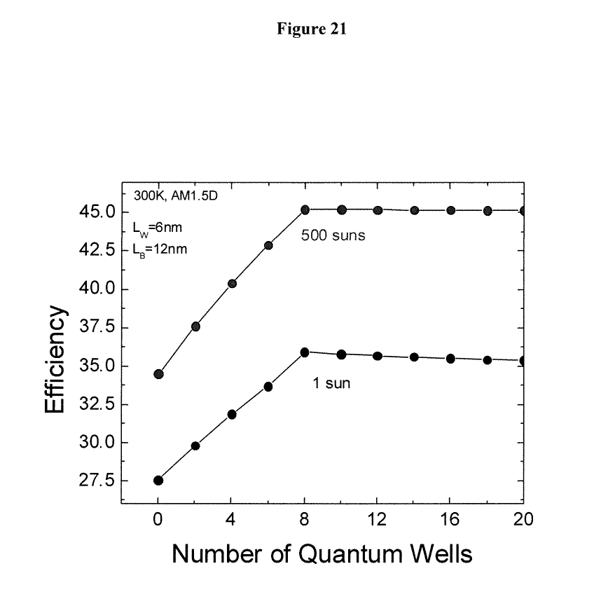

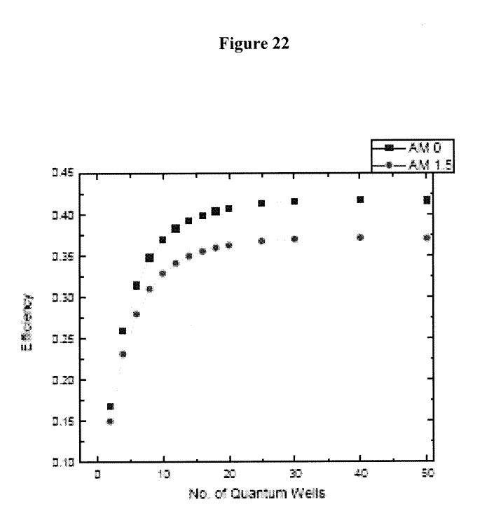

The drift-diffusion model was utilized to estimate the efficiency of the 4 junction and 3 junction configurations (FIGS. 21 and 22) in AM1.5 and 500 sun concentration, where we obtain the efficiency in the 40% and 50% range respectively, which is not substantially changed from the values earlier reported. This shows that incorporating the above alterations does not change the practical efficiency expected from the design.

### Conclusions

Improving upon the previous work where the dilute nitride quantum well design was modeled, the effect of the electric field as well as the incorporation of strain balancing were added in this work to obtain a more realistic estimate of the efficiency of such a device. The results show that there is little or no degradation in the overall performance of the device, and the practical estimates of efficiency are under 500 suns at AM1.5 in excess of 45%, while reaching up to 40% under AM1.5 for the quadruple junction configuration.

The present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee.

### REFERENCES CITED

The following references, to the extent that they provide exemplary procedural or other details supplementary to those set forth herein, are specifically incorporated herein by reference.

### U.S. Patent Documents

U.S. Pat. No. 6,372,980 issued on Apr. 16, 2002, with Freundlich et al. listed as inventors.
U.S. Pat. No. 6,147,296 issued on Nov. 14, 2000, with Freundlich et al. listed as inventors.

### Non-Patent References

A. Freundlich and A. Alemu, Phys. Stat. Sol. C 2(8), 2978 (2005)
A. Freundlich, A. Fotkatzikis, L. Bhusal, L. Williams, A. Alemu, W. Zhu, J. A. H. Coaquira, A. Feltrin, and G. Radhakrishnan, J. Vac. Sci. Technol. B 25 (3), (2007)
A. Khan, S. R. Kurtz, S. Prasad, S. W. Johnston, and J. Gou, Applied Physics Letters, 90, 243509 (2007)
A. Lindsay and E. P. O'Reilly, Phys. Rev. Lett. Vol. 93, 196402 (2004)
A. Lindsay and E. P. O'Reilly, Phys. Rev. Lett. Vol. 93, 196402 (2004)
A. Lindsay, S. Tomi, E. P. O'Reilly, Solid-State Electronics 47 (2003) 443-446
C. Baur, A. W. Bett, F. Dimroth, S. V. Riesen, B. Kunert, M. Traversa, K. Volz, W. Stolz, Proceedings of the WCPEC-3, Osaka, Japan, (2003), pp. 677
C. G. Van de Walle, Phys. Rev. B 39, 1871 (1981)
C. Monier, A. Freundlich, M. F. Vilela, Journal of Applied Physics, Vol. 85, No. 5 (1999)
C. Skierbiszewski, S.P. Lepkowski, P. Perlina, T. Suski, W. Jantsch, and J. Geisz Physica E 13 (2002) 1078-1081
D. B. Jackrel, S. R. Bank, H. B. Yuen, M. A. Wistey, J. S. Harris, A. J. Ptak, S. W. Johnston , D. J. Friedman, and S. R. Kurtz, J. Appl. Phys. 101, 114916 (2007) 10.1063/1.2744490
D. Kwon, R. J. Kaplar, S. A. Ringel, A. A. Allerman, S. R. Kurtz, E. D. Jones, Appl. Phys Lett 74 (19) (1999) 2830
D. J. Friedman, S. R. Kurtz. Prog. Photovoltaics 10 (2002) 331
E. O. Kane, in Handbook on Semiconductors, edited by T. S. Moss, North-Holland, Amsterdam, 1982, Vol. 1, Chap. 4A, pp. 193-217
E. O. Kane, in Physics of III-V Compounds, edited by R. K. Willardson and A. C. Beer, Semiconductors and Semimetals, Academic, New York, 1966, Vol. I, p. 75.
G. Bastard, Wave Mechanics Applied to Semiconductor Heterostructures, Halstead, New York, (1988)
G. Vijaya, A. Alemu, A. Freundlich, Proceedings of the 35th IEEEPVSC pp. 380-384, (2010)
H. Hassan and H. N. Spector, Journal of Vac. Sc. Tech A, 3 (1), (1985)
H. Q. Hou, K. C. Reinhardt, S. R. Kurtz, J. M. Gee, P. C. Chang and B. E. Hammons: Device Research Conf. Dig. 1998, 56th Annual (IEEE, NJ, 1998) p. 64
J. B. Héroux, X. Yang, and W. I. Wang, J. Appl. Phys. 92, 4361 (2002)
J. Ibá\ddot{n}ez, R. Cuscó, E. Alarcón-Lladó, L. Artús, A. Patanè, D. Fowler, L. Eaves, K. Uesugi, and I. Suemune, J. Appl. Phys. 103, 103528 (2008)
L. Bhusal and A. Freundlich, Physical Review B 75, 075321(2007)
L. Bhusal, A. Alemu, and A. Freundlich, Phys. Rev. B 72, 073309 (2005)
M. A. Green, K. Emery, D. L. King, Y. Hishikawa, and W. Warta, Prog. Photovolt: Res. Appl. (2009) 17:85-94.
M. H. Gass, A. J. Papworth, T. B. Joyce, T. J. Bullough, and P. R.Chalker, Appl. Phys. Lett. 84, 1453 (2004)
M. M. Dignam and J. E Sipe, Phys. Rev. B 43, 5 (1991)
Markus Weyers and Michio Sato, Appl. Phys. Lett. 62 (12) pp.1396 (1993)
P. J. Klar, H. Grüning, W. Heimbrodt, J. Koch, F. Höhnsdorf, W. Stolz, P. M. A. Vicente, and J. Camassel, Appl. Phys. Lett. 76, 3439 (2000)
S. L. Chuang, Physics of Optoelectronic Devices, Wiley, New York, (1995)
S. Turcotte, J.-N. Beaudry, R. A. Masut, P. Desjardins, G. Bentoumi, and R. Leonelli, J. Appl. Phys. 104, 083511 (2008)
S. Y. Xie, S. F. Yoon, S. Wang, J. Appl. Phys 97 (7), (2005) 073702.
Shan W, Walukiewicz W, Ager III J W, Haller E E, Geisz J F, Friedman D J, et al. Band anticrossing in GaInNAs alloys. Phys Rev Lett (1999) 82(III):1221-4.
Steven R. Kurtz, A. A. Allerman, E. D. Jones, J. M. Gee, J. J. Banas, Appl. Phys. Lett., Vol. 74, pp. 729-731 (1999)
W. Li, M. Pessa, J. Toivonen, H. Lipsanen, Phys. Rev B 64, (2001) 113308
W. T. Masselink, P J Pearah, J Klem, C K Peng, H Morkoc, G. D. Sanders and Yia-Chung Chang Phys. Rev. B 32, 12 (1985)
Yu Wen, Yunpeng Wang, Sugiyama, M., Nakano, Y. Proceedings of the 35th IEEEPVSC pp. 385-388, (2010)

What is claimed:

1. A multi-junction solar cell, comprising:
two or more subcells where at least one of the subcells contains a plurality of quantum wells fabricated with III-V semiconductor alloys containing Ga, As, and up to 5% nitrogen and having a confined bandgap smaller than 1.3 eV at room temperature

2. The multi-junction solar cell of claim 1, wherein one of the subcells comprises alloys of AlGaInP with a bandgap in the 1.7 eV to 2.15 eV.

3. The multi-junction solar cell of claim 1, wherein one of the subcells comprises Ge with a bandgap of 0.66 eV.

4. The multi junction solar cell of claim 1, wherein one of the subcells comprises alloys containing Ga and As with a bandgap in the range of 1.3 eV to 1.5 eV.

5. The triple junction solar cell of claim 1, wherein the bandgap of a first subcell is 1.8 eV and a second subcell contains 10-50 periods of pseudomorphically strained GaAs1-xNx/GaAs quantum wells with nitrogen composition x=0.02 to x=0.035 and a confined bandgap of about 1.1 eV.

6. The triple junction solar cell of claim 1, wherein the bandgap of a first subcell is about 1.9 eV, a second subcell bandgap is about 1.4 eV and the bottom cell contains 10-50 periods of pseudomorphically strained GaAs1-xNx/GaAs quantum wells with nitrogen composition x=0.03 to x=0.04 and a confined bandgap of about 1 eV.

7. The triple junction solar cell of claim 1, wherein the bandgap of a first subcell is about 2 eV, a second subcell bandgap is about 1.4 eV and the bottom cell contains 10-50 periods of pseudomorphically strained GaAs1-xNx/GaAs quantum wells with nitrogen composition x=0.03 to x=0.04 and a confined bandgap of about 1 eV.

8. The quadruple junction solar cell of claim 1, wherein the bandgap of a first subcell is about 2 eV, a second subcell has a bandgap of about 1.4 eV and a third subcell contains 10-50 periods of pseudomorphically strained GaAs1-xNx/GaAs quantum wells with nitrogen composition x=0.03 to x=0.04 and a confined bandgap of about 1 eV.

9. The multi -junction solar cell of claim 1, wherein one of he subcells contains a plurality of quantum wells that are lattice matched to GaAs or Ge.

10. The multi junction solar cell of claim 1, wherein one of the subcells contains a plurality of quantum wells that are strain balanced to GaAs or Ge.

11. The multi-junction solar cell of claim 9, wherein the quantum wells are fabricated with quaternary alloys of InGaAsN or GaAsNSb or quinternary alloys of InGaAsNSb or InGaAsPN or GaAsPSbN

12. The multi-junction solar cell of claim 10, wherein the ternary GaAsN wells are strain balanced by alloys containing GaAsSb or GaInAs barriers.

13. The multi-junction solar cell of claim 12, wherein one of the subcells comprises alloys of A1GaInP with a bandgap in the 1.7 eV to 2.15 eV.

14. The multi junction solar cell of claim 12, wherein one of the subcells is made with Ge with a bandgap of 0.66 eV.

15. The multi-junction solar cell of claim 12, wherein one of the subcells comprises alloys containing Ga and As with a bandgap in the range of 1.3 eV to 1.5 eV.

16. The triple junction solar cell of claim 12, wherein the bandgap of a first subcell is 1.8 eV and a second subcell contains 5-30 periods of strain-compensated GaAs1-xNx/GaAsSb quantum wells with nitrogen composition x=0.02 to x=0.035 and a confined bandgap of about 1.1 eV.

17. The triple junction solar cell of claim 12, wherein the bandgap of a first subcell is about 1.9 eV, a second subcell bandgap is about 1.4 eV and the bottom cell contains 10-50 periods of strain-compensated GaAs1-xNx/GaAsSb quantum wells with nitrogen composition x=0.03 to x=0.04 and a confined bandgap of about 1 eV.

18. The triple junction solar cell of claim 12, wherein the bandgap of a first subcell is about 2 eV, a second subcell bandgap is about 1.4 eV and the bottom cell contains 10-50 periods of strain-compensated GaAs1-xNx/GaAsSb quantum wells with nitrogen composition x=0.03 to x=0.04 and a confined bandgap of about 1 eV.

19. The quadruple junction solar cell of claim 12, wherein the bandgap of a first subcell is about 2 eV, a second subcell top has a bandgap of about 1.4 eV and a third subcell contains 10-50 periods of strain-compensated GaAs1-xNx/GaAsSb quantum wells with nitrogen composition x=0.03 to x=0.04 and a confined bandgap of about 1 eV.
